(19) United States
(12) Patent Application Publication
(10) Pub. No.: US 2023/0389192 A1
(43) Pub. Date: Nov. 30, 2023

(54) DISPLAY APPARATUS

(71) Applicant: Samsung Display Co., Ltd., Yongin-si (KR)

(72) Inventors: MINGU KIM, Yongin-si (KR); KYOUNGAH LEE, Yongin-si (KR); EUNHYE KANG, Yongin-si (KR); HYUNJUN KIM, Yongin-si (KR); YU DEOK SEO, Yongin-si (KR); HYOYUL YOON, Yongin-si (KR)

(21) Appl. No.: 18/117,211

(22) Filed: Mar. 3, 2023

(30) Foreign Application Priority Data
May 24, 2022 (KR) 10-2022-0063684

(51) Int. Cl. H05K 5/00; H10K 59/38; H10K 59/80; H10K 59/50

(52) U.S. Cl. CPC H05K 5/0004; H10K 59/38; H10K 59/87; H10K 59/50

(57) ABSTRACT

A display apparatus includes a display panel including an upper end and a lower end extending in a first direction and a left end and a right end extending along a second direction crossing the first direction, where the display panel is curved with respect to a central axis extending along the second direction, a bottom chassis disposed on the rear surface of the display panel, and a coupling member disposed between the display panel and the bottom chassis, where the coupling member includes a first coupling part disposed adjacent to the left end, a second coupling part disposed adjacent to the right end, a third coupling part extending along the second direction and crossing the central axis, a fourth coupling part parallel to the third coupling part and crossing the central axis, and a fifth coupling part disposed outside of the first to fourth coupling parts.

This application claims to Korean Patent Application No. 10-2022-0063684, filed on May 24, 2022, and all the benefits accruing therefrom priority under 35 U.S.C. § 119, the content of which in its entirety is herein incorporated by reference.

### BACKGROUND

### 1. Field

The disclosure herein relates to a display apparatus, and more particularly to, a curved display apparatus.

### 2. Description of the Related Art

A display apparatus displays various images on a display screen to provide information to a user. In general, the display apparatus displays the information within an allotted screen. The display apparatus may be utilized to display images in various electronic devices such as smart phones, laptops, televisions, and the like.

Recently, a display apparatus may include a curved display surface to provide sense of presence and sense of immersion to a user. In addition, a display apparatus may be provided with a narrow bezel, so that the aesthetic appeal of the display apparatus may also be improved.

### SUMMARY

In a curved display apparatus with a narrow bezel, the curved display apparatus is desired to be stably assembled to maintain its curved shape while being used.

Embodiments of the disclosure provide a curved display apparatus stably assembled.

An embodiment of the invention provides a display apparatus including a display panel including an upper end and a lower end extending in a first direction and a left end and a right end extending along a second direction crossing the first direction, where the display panel is curved with respect to a central axis extending along the second direction, a bottom chassis disposed on a rear surface of the display panel, and a coupling member disposed between the display panel and the bottom chassis to attach the display panel and the bottom chassis to each other, where the coupling member includes a first coupling part extending along the first direction, spaced apart from the central axis and disposed adjacent to the left end of the display panel, a second coupling part parallel to the first coupling part, spaced apart from the first coupling part having the central axis interposed therebetween and disposed adjacent to the right end of the display panel, a third coupling part extending along the second direction and crossing the central axis, a fourth coupling part parallel to the third coupling part and crossing the central axis, and a fifth coupling part disposed along at least a portion of an edge of the display panel and disposed outside of the first to fourth coupling parts.

In an embodiment, the bottom chassis may cover the rear surface of the display panel and may expose a side surface of the display panel.

In an embodiment, the fifth coupling part may include a first portion attached to the left end of the display panel, a second portion attached to the right end of the display panel and bent from the first portion, and a third portion attached to the upper end of the display panel and bent from the second portion.

In an embodiment, the coupling member may further include a sixth coupling part disposed on a lower side of the fourth coupling part and attached to the lower end of the display panel, where the sixth coupling part may include a plurality of patterns arranged in the second direction.

In an embodiment, a separation distance between the first coupling part and the left end of the display panel may be in a range of approximately 4% to approximately 7% of a length of the upper end of the display panel.

In an embodiment, the separation distance between the first coupling part and the lower end of the display panel may be approximately 40 mm or less.

In an embodiment, the coupling member may further include a seventh coupling part disposed on a lower side of the fourth coupling part, and disposed between the first coupling part and the second coupling part, where the seventh coupling part may include a first left pattern and a first right pattern disposed spaced apart from each other in the first direction.

In an embodiment, the seventh coupling part may further include a center pattern disposed between the fourth coupling part and the third coupling part, disposed between the first coupling part and the second coupling part, and overlapping the central axis on a plane.

In an embodiment, the seventh coupling part may further include a second left pattern and a second right pattern disposed between the third coupling part and the fifth coupling part, and disposed spaced apart from each other in the first direction.

In an embodiment of the invention, a display apparatus includes a display unit including a base substrate, a light emitting element disposed on the base substrate, and an encapsulation layer disposed on the light emitting element, a functional unit including a window substrate opposing the base substrate and a light control layer disposed on a rear surface of the window substrate and including a wavelength conversion material, and a sealing layer disposed between the display unit and the functional unit, where the sealing layer may be disposed on a front surface of the display panel.

In an embodiment, the wavelength conversion materials may include quantum dots.

In an embodiment, each of the base substrate and the window substrate may include glass.

In an embodiment, the coupling member may be a foam-type tape.

In an embodiment of the invention, a display apparatus includes a display panel including an upper end and a lower end extending in a first direction and a left end and a right end extending along a second direction crossing the first direction, where the display panel is curved with respect to a central axis extending along the second direction, a bottom chassis disposed on a rear surface of the display panel, and a coupling member disposed between the display panel and the bottom chassis to attach the display panel and the bottom chassis, where the coupling member includes a first coupling part parallel to a central axis and disposed adjacent to the left end, a second coupling part parallel to the central axis, and spaced apart from the first coupling part with the central axis interposed therebetween and disposed adjacent to the right end, and a third coupling part extending along the left end, the upper end, and the right end, where the first coupling part and the second coupling part are disposed in a space surrounded by the third coupling part.

In an embodiment, each of a separation distance between the first coupling part and the left end and a separation distance between the second coupling part and the right end may be in a range of approximately 4% to approximately 7% of a length of the upper end of the display panel.

In an embodiment, each of a separation distance between the first coupling part and the lower end and a separation distance between the second coupling part and the lower end may be approximately 40 millimeters (mm) or less.

In an embodiment, the coupling member may further include a fourth coupling part and a fifth coupling part, each of which is extending along the first direction and disposed spaced apart from each other in the second direction, and each of which is disposed overlapping the central axis, where the fourth coupling part and the fifth coupling part may be disposed in a space surrounded by the third coupling part.

In an embodiment, the coupling member may further include a plurality of first patterns disposed adjacent to the fifth coupling part and spaced apart from each other.

In an embodiment, the coupling member may further include a plurality of second patterns disposed adjacent to the fourth coupling part, spaced apart from each other in the first direction, and spaced apart from the first patterns in the second direction, where the second patterns may be spaced apart from each other with the central axis interposed therebetween.

In an embodiment, the display panel may include quantum dots.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain principles of the invention. In the drawings:

FIG. 1 is an assembled perspective view of a display apparatus according to an embodiment of the invention;

FIG. 2 is an exploded perspective view of the display apparatus illustrated in FIG. 1;

FIG. 3A is a cross-sectional view schematically illustrating the structure of a display panel according to an embodiment of the invention;

FIG. 3B is an enlarged cross-sectional view showing a portion of a display panel according to an embodiment of the invention;

FIG. 4 is a plan view illustrating a part of the configuration of a display apparatus according to an embodiment of the invention;

FIG. 5 is a plan view of a coupling member according to an embodiment of the invention;

FIG. 6A to FIG. 6D are plan views illustrating coupling members according to embodiments of the invention; and

FIG. 7A to FIG. 7D are cross-sectional views schematically illustrating a process of assembling a display apparatus according to an embodiment of the invention.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

In the disclosure, when an element (or a region, a layer, a portion, etc.) is referred to as being “on,” “connected to,” or “coupled to” another element, it means that the element may be directly disposed on/connected to/coupled to the other element, or that a third element may be disposed therebetween.

Like reference numerals refer to like elements. Also, in the drawings, the thickness, the ratio, and the dimensions of elements are exaggerated for an effective description of technical contents.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms “first,” “second,” etc. may be used herein to describe various elements, these elements should not be limited by these terms. These terms are only used to distinguish one element from another. For example, a first element may be referred to as a second element, and a second element may also be referred to as a first element in a similar manner without departing the scope of rights of the invention. The terms of a singular form may include plural forms unless the context clearly indicates otherwise.

In addition, terms such as “below,” “lower,” “above,” “upper,” and the like are used to describe the relationship of components shown in the drawings. The terms are used as a relative concept and are described with reference to the direction indicated in the drawings.

Unless otherwise defined, all terms (including technical and scientific terms) used herein have the same meaning as commonly understood by one of ordinary skill in the art to which the invention pertains. It is also to be understood that terms defined in commonly used dictionaries should be interpreted as having meanings consistent with the meanings in the context of the related art, and are expressly defined herein unless they are interpreted in an ideal or overly formal sense.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention will be described in detail with reference to the accompanying drawings.

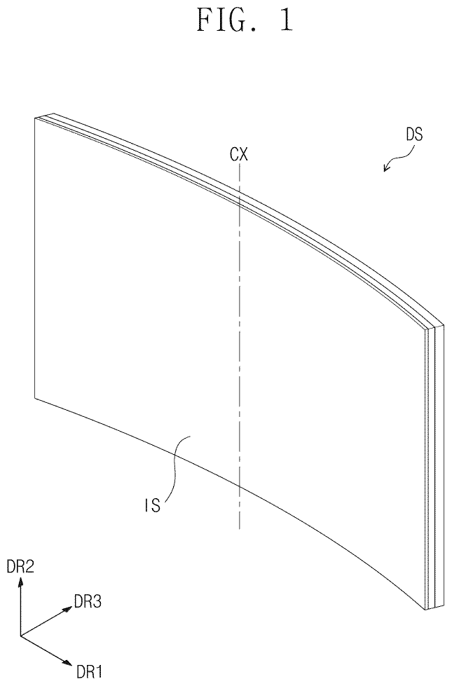

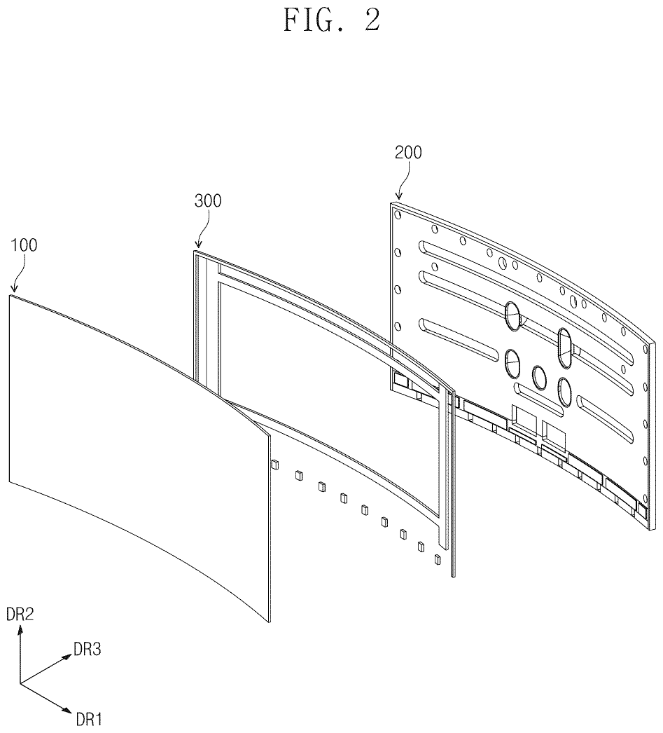

FIG. 1 is an assembled perspective view of a display apparatus according to an embodiment of the invention, and FIG. 2 is an exploded perspective view of the display device illustrated in FIG. 1. Hereinafter, an embodiment of the display device according to the invention will be described with reference to FIG. 1 and FIG. 2.

As illustrated in FIG. 1, an embodiment of a display apparatus DS may have a curved shape. In such an embodiment, the display apparatus DS may have a curved shape along a first direction DR1. In such an embodiment, the display apparatus DS may be bent along the first direction DR1 about an axis (hereinafter, a central axis) parallel to a second direction DR2 which crosses the first direction DR1. A display surface IS of the display apparatus DS may have a concave shape toward the front in a third direction DR3. The third direction DR3 may correspond to a thickness direction of the display apparatus DS. In such an embodiment where the concave display surface IS is provided, the display apparatus DS may improve a user's sense of immersion and sense of presence with respect to an image.

Referring to FIG. 2, an embodiment of the display apparatus DS may include a display panel 100, a bottom chassis 200, and a coupling member 300. The display panel 100, the bottom chassis 200, and the coupling member 300 may be sequentially stacked along the third direction DR3.

The display panel 100 provides the display surface IS. The display panel 100 may have a curved shape along the second direction DR2 with respect to a central axis CX. The display panel 100 may have a curved shape in a quadrangular shape. Specifically, the display panel 100 includes an upper end and a lower end, which are each extending along the first direction DR1 and are parallel to each other in the second direction DR2 while facing each other, and includes a left end and a right end which are each extending along the second direction DR2 and are parallel to each other in the first direction DR1 while facing each other.

The display panel 100 displays an image based on an electrical signal. The display panel 100 may be one of various types of display panels, such as an organic light emitting display panel, a quantum dot display panel, a liquid crystal display panel, and the like. The display panel 100 will be described later in greater detail.

In an embodiment, a circuit board for driving the display panel 100, a power board for providing power, or the like may be further provided and connected to the display panel 100, but is omitted in the FIG. 2 for convenience of illustration and description.

The bottom chassis 200 is disposed on a rear surface of the display panel 100. The bottom chassis 200 has a curved shape to correspond to the display panel 100. The bottom chassis 200 may be provided in a shape substantially corresponding to a shape of the display panel 100 on a plane. That is, the bottom chassis 200 may cover the rear surface of the display panel 100 while exposing a side surface of the display panel 100. According to an embodiment of the invention, a bezel of the display apparatus DS may only be substantially determined by a dead space DS shown on the display surface IS of the display panel 100. Accordingly, the display device DS with a reduced bezel may be provided. However, this is only an example. In the display apparatus DS according to an embodiment of the invention, an additional protective member for covering the side surface of the display panel 100 may be included, but the invention is not limited to any one embodiment.

The coupling member 300 physically couples the display panel 100 and the bottom chassis 200 to each other. The coupling member 300 may be a tape with elasticity. In an embodiment, for example, the coupling member 300 may be a structural body in which a foam tape or sponge is coupled to an adhesive member. The coupling member 300 may prevent the display panel from being separated due to the repulsive force of the display panel 100 and to prevent the transfer of impact between the display panel 100 and the bottom chassis 200.

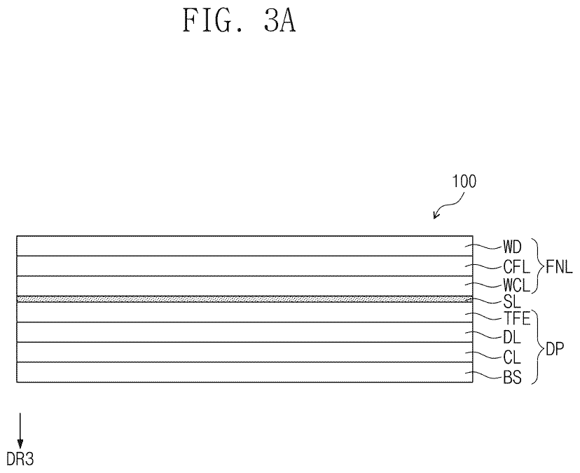

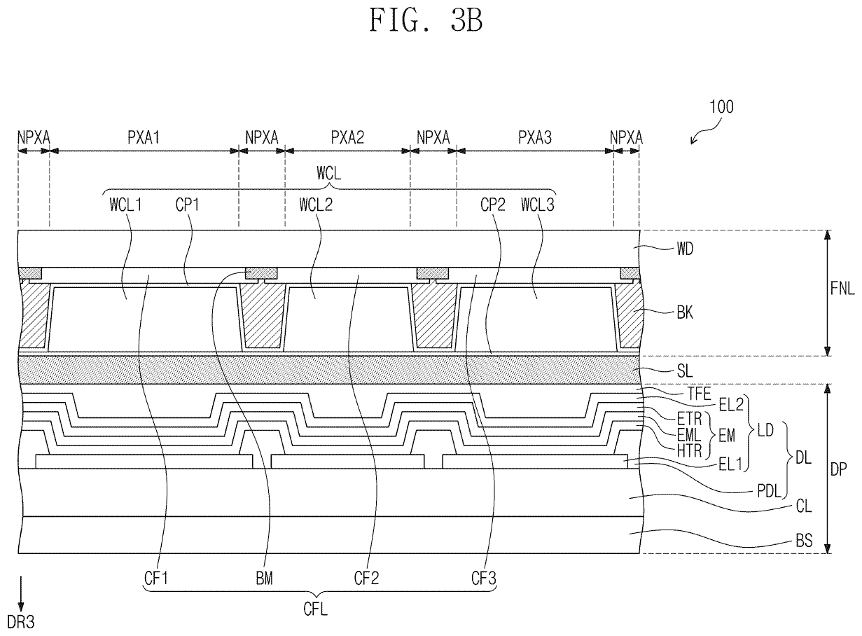

FIG. 3A is a cross-sectional view schematically illustrating the structure of a display panel according to an embodiment of the invention, and FIG. 3B is an enlarged cross-sectional view showing a portion of a display panel according to an embodiment of the invention. Hereinafter, an embodiment of the display panel 100 will be described with reference to FIG. 3A and FIG. 3B.

In an embodiment, the display panel 100 may include a display unit DP, a sealing layer SL, and a functional layer FNL. The sealing layer SL is disposed between the display unit DP and the functional layer FNL to couple the display unit DP and the functional layer FNL to each other and encapsulate the display unit DP and the functional layer FNL.

In an embodiment, the display unit DP may include a base substrate BS, a circuit layer CL, and a display layer DL. In an embodiment, the base substrate BS, the circuit layer CL, and the display layer DL may be sequentially stacked in the third direction DR3.

The base substrate BS may be a member which provides a base surface on which the display layer DL is disposed. The base substrate BS may include glass, a metal, or a synthetic resin. The base substrate BS may be rigid or flexible. In an embodiment of the invention, the base substrate BS may be rigid. The repulsive force of the display unit DP may be largely affected by the base substrate BS.

In an embodiment, the circuit layer CL may be disposed on the base substrate BS, and the circuit layer CL may include a plurality of transistors (not shown). The transistors (not shown) may each include a control electrode, an input electrode, and an output electrode. In an embodiment, for example, the circuit layer CL may include a switching transistor and a driving transistor for driving the light emitting element layer LD.

In an embodiment, the circuit layer CL may be disposed on the base substrate BS, and the circuit layer CL may include a plurality of transistors (not shown). The transistors (not shown) may each include a control electrode, an input electrode, and an output electrode. In an embodiment, for example, the circuit layer CL may include a switching transistor and a driving transistor for driving the light emitting element layer LD.

In an embodiment, the circuit layer CL may be disposed on the base substrate BS, and the circuit layer CL may include a plurality of transistors (not shown). The transistors (not shown) may each include a control electrode, an input electrode, and an output electrode. In an embodiment, for example, the circuit layer CL may include a switching transistor and a driving transistor for driving a light emitting element layer LD of the display layer DL.

In an embodiment, as shown in FIG. 3B, the display layer DL may include a pixel definition film PDL and the light emitting element layer LD. In an embodiment, the pixel definition film PDL may be disposed on the circuit layer CL. The pixel definition film PDL may include a polymer resin. In an embodiment, for example, the pixel definition film PDL may be formed by including a polyacrylate-based resin or a polyimide-based resin. In an embodiment, the pixel definition film PDL may be formed by further including an inorganic material in addition to the polymer resin. In an embodiment, the pixel definition film PDL may be formed by including a light absorbing material, or may be formed by including a black pigment or a black dye. Also, the pixel definition film PDL may include or be formed of an inorganic material. In an embodiment, for example, the pixel definition film PDL may be formed by including silicon nitride (SiNx), silicon oxide (SiOx), silicon oxide (SiOxNy), or the like. The pixel definition film PDL may define light emitting regions PXA1, PXA2, and PXA3. In an embodiment, the light emitting regions PXA1, PXA2, and PXA3 and a non-light emitting region NPXA may be separated by the pixel definition film PDL.

The light emitting element layer LD may include a first electrode EL1 and a second electrode EL2 which face each other, and a light emitting unit EM disposed between the first electrode EL1 and the second electrode EL2.

The first electrode EL1 may be disposed on the circuit layer CL. The first electrode EL1 may be electrically connected to a driving transistor (not shown) to receive a driving signal. The first electrode EL1 may be disposed spaced apart from each other and in an opening defined in the pixel definition film PDL. The first electrode EL1 has conductivity. The first electrode EL1 may include or be formed of a metal alloy or a conductive compound. The first electrode EL1 may be an anode. In an embodiment, the first electrode EL1 of the light emitting element LD may be a reflective electrode. However, the embodiment of the invention is not limited thereto. In an embodiment, for example, the first electrode EL1 may be a transmissive electrode or a transflective electrode, and the like.

In an embodiment, the light emitting unit EM may be disposed on the first electrode ELL The light emitting unit EM may include a hole transport region HTR, a light emitting layer EML, and an electron transport region ETR. In an embodiment, for example, the hole transport region HTR may include a hole injection layer and a hole transport layer, and a hole injection material and a hole transport material known in the art may be respectively used for the hole injection layer and the hole transport layer.

The light emitting layer EML is provided on the hole transport region HTR. The light emitting layer EML may have a single-layered structure having a single layer formed of a single material, a single-layered structure having a single layer formed of a plurality of different materials, or a multi-layered structure having a plurality of layers formed of a plurality of different materials.

In an embodiment, the light emitting layer EML may be a single layer commonly provided to the plurality of light emitting regions PXA1, PXA2, and PXA3. Accordingly, the display unit DP may emit light of the same wavelength region regardless of the light emission regions PXA1, PXA2, and PXA3. The light emitting layer EML may emit a first color light. That is, the display unit DP may emit the first color light. In an embodiment, for example, the light emitting layer EML may include an organic material, a fluorescent material, or a phosphorescent material which emits blue light. However, this is an example, and the light emitting layer EML may be formed of a plurality of light emitting patterns divided for each of the light emitting regions PXA1, PXA2, and PXA3, and is not limited to any one embodiment.

The electron transport region ETR is provided on the light emitting layer EML. The electron transport region ETR may include at least one selected from an electron transport layer and an electron injection layer, but is not limited thereto. In an embodiment where the electron transport region ETR includes the electron injection layer and the electron transport layer, an electron injection material and an electron transport material in the art may be respectively used for the electron injection layer and the electron transport layer.

The second electrode EL2 may be disposed on the first electrode EL1. At least one light emitting unit EM may be disposed between the first electrode EL1 and the second electrode EL2. The second electrode EL2 may be a common electrode or a cathode. The second electrode EL2 may include or be formed of a metal alloy or a conductive compound. The second electrode EL2 may be a transmissive electrode, a transflective electrode, or a reflective electrode. In an embodiment, where the second electrode EL2 is a transmissive electrode, the second electrode EL2 may include or be formed of a transparent metal oxide, for example, indium tin oxide (ITO), indium zinc oxide (IZO), zinc oxide (ZnO), indium tin zinc oxide (ITZO), or the like.

The thin film encapsulation layer TFE may be disposed on the second electrode EL2. The thin film encapsulation layer TFE may be directly disposed second electrode EL2. The thin film encapsulation layer TFE may be a single layer, or a plurality of stacked layers. The thin film encapsulation layer TFE may include an organic film and/or an inorganic film.

In an embodiment, as shown in FIG. 3B, the functional layer FNL may include a window WD, a color filter layer CFL, a light control layer WCL, and a bank BK.

The window WD may include or be formed of a material including glass, sapphire, or plastic. The window WD may include a transmissive region which transmits light emitted from the light control layer WCL, and a light blocking region which is adjacent to the transmissive region and through which light is not transmitted. The repulsive force of the functional layer FNL may be substantially generated by the window WD.

In an embodiment, the color filter layer CFL may be disposed on a lower surface of the window WD. The color filter layer CFL may include a first color filter CF1, a second color filter CF2, a third color filter CF3, and a plurality of light blocking members BM. The first to third color filters CF1, CF2, and CF3 may be disposed spaced apart from each other. The plurality of light blocking members BM may be disposed between the first to third color filters CF1, CF2, and CF3.

The first color filter CF1 may overlap a first light control unit WCL1, the second color filter CF2 may overlap a second light control unit WCL2, and the third color filter CF3 may overlap a third light control unit WCL3. The first light control unit WCL1 to the third light control unit WCL3 will be described later. Each of the first to third color filters CF1, CF2, and CF3 may transmit a different wavelength. In an embodiment, for example, the first color filter CF1 may transmit a second color light and absorb the other light, the second color filter CF2 may transmit a third color light and absorb the other light, and the third color filter CF3 may transmit the first color light and absorb the other light.

Each of the first to third color filters CF1, CF2, and CF3 may transmit color light corresponding to light emitted from the first to third light control units WCL1, WCL2, and WCL3, and absorb the other light. The first color filter CF1 may be a red color filter which transmits red light, the second color filter CF2 may be a green color filter which transmits green light, and the third color filter CF3 may be a blue color filter which transmits blue light.

The first to third color filters CF1, CF2, and CF3 may include at least one dye or pigment dispersed between resins. The first to third color filters CF1, CF2, and CF3 may include different types of dyes and pigments from each other. In an embodiment, for example, the first color filter CF1 may include at least one red dye or red pigment, the second color filter CF2 may include at least one green dye or green pigment, and the third color filter CF3 may include at least one blue dye or blue pigment. However, the embodiment of the invention is not limited thereto.

In such an embodiment where the first to third color filters CF1, CF2, and CF3 are provided, only the light of a target wavelength region is emitted, so that the color reproducibility of the display apparatus DS may be increased. In such an embodiment, since light incident from the outside is absorbed, and thus, external light reflection is reduced, the visibility of the display device DS may be improved.

In an embodiment, the plurality of light blocking members BM may be disposed between the first to third color filters CF1, CF2, and CF3. The plurality of light blocking members BM may be directly disposed in the lower portion of the window WD. The plurality of light blocking members BM may be a black matrix. The plurality of light blocking members BM may be formed by including an organic light blocking material or an inorganic light blocking material which includes a black pigment or a black dye. In an embodiment, for example, the plurality of light blocking members BM may include carbon black particles. The plurality of light blocking members BM may prevent a light leakage phenomenon, and may define gaps between a plurality of color filters CF1, CF2, and CF3.

The plurality of light blocking members BM may overlap the non-light emitting region NPXA on a plane or in the thickness direction of the display panel DP or in the third direction DR3. Since the plurality of light blocking members BM are disposed, a phenomenon in which light emitted from adjacent pixel regions are mixed may be effectively prevented.

In an embodiment, the light emitting regions PXA1, PXA2, and PXA3 may have different areas depending on colors emitted from the plurality of light control units WCL1, WCL2, and WCL3. In an embodiment, for example, a red light emitting region PXA1 corresponding to the first light control unit WCL1 transmitting a red light may have the largest area, and a green light emitting region PXA2 corresponding to the second light control unit WCL2 generating and then emitting a green light may have the smallest area. However, the embodiment of the invention is not limited thereto, and the light emitting regions PXA1, PXA2, and PXA3 may emit light of different colors other than the red light, the green light, and the blue light. Alternatively, the light emitting regions PXA1, PXA2, and PXA3 may have a same area as each other, or may have an area different from that shown in FIG. 3B, and are not limited to any one embodiment.

The bank BK may be disposed in a lower portion of the color filter layer CFL. The bank BK is disposed corresponding to the non-light emitting region NPXA. In an embodiment, openings corresponding to the light emitting regions PXA1, PXA2, and PXA3 may be defined in the bank BK. The bank BK may include an insulation material. The bank BK may include an inorganic substance or an organic substance. In addition, the bank BK may be formed by including a light absorbing material, or may further include a black pigment or a black dye. Alternatively, the bank BK may further include a metal and the like for increasing heat dissipation, and is not limited to any one embodiment.

In an embodiment, a light control layer WCL may be disposed on a lower surface of the color filter layer CFL. The light control layer WCL may absorb light emitted from the light emitting element layer LD to emit light having a center wavelength of a wavelength region different from that of the absorbed light, or may transmit light emitted from the light emitting element layer LD.

In an embodiment, the light control layer WCL may include the first light control unit to the third light control unit WCL1, WCL2, and WCL3. Each of the first light control unit to the third light control unit WCL1, WCL2, and WCL3 may be disposed in the openings defined in the bank BK to be disposed overlapping the light emitting regions PXA1, PXA2, and PXA3.

The first light control unit WCL1 may include a quantum dot for converting the first color light into the second color light. The second light control unit WCL2 may include a quantum dot for converting the first color light into the third color light. The third light control unit WCL3 may not include a quantum dot. The third light control unit WCL3 may transmit the first color light. The second color light may be light having a longer wavelength than the first color light and the third color light. The third color light may be light having a longer wavelength than the first color light. In an embodiment, for example, the first color light may be blue light, the second color light may be red light, and the third color light may be green light. In addition, the first color light may be light provided from the display unit DP to the light control layer WCL.

A quantum dot may be a particle for converting the wavelength of the light provided from the display unit DP. The quantum dot may be selected from a Group II-VI compound, a Group III-V compound, a Group IV-VI compound, a Group IV element, a Group IV compound, and a combination thereof.

The quantum dot may have a full width of half maximum (FWHM) of a light emission wavelength spectrum of about 45 nanometers (nm) or less, preferably about 40 nm or less, for example, about 30 nm or less, and color purity or color reproducibility may be improved in the above range. In addition, light emitted through the quantum dot is emitted in all directions, so that a wide viewing angle may be improved.

In addition, although the form of the quantum dot is not particularly limited as long as it is in a form commonly used in the art, a quantum dot in the form of, more specifically, spherical, pyramidal, multi-arm, or cubic nanoparticles, nanotubes, nanowires, nanofibers, nanoplate particles, and the like may be used.

The quantum dot may control the color of emitted light according to the particle size, and accordingly, the quantum dot may have various luminous colors such as blue, red, green, and the like. The smaller the particle size of the quantum dot, the shorter the wavelength region of light emitted. In an embodiment, for example, the particle size of a quantum dot emitting green light may be smaller than the particle size of a quantum dot emitting red light.

In an embodiment, the functional layer FNL may further include a plurality of capping layers CP1 and CP2. The plurality of capping layers CP1 and CP2 may be disposed to cover the plurality of light control units WCL1, WCL2, and WCL3 and the bank BK. The plurality of capping layers CP1 and CP2 may prevent the penetration of moisture, oxygen, and the like. The plurality of capping layers CP1 and CP2 may be disposed adjacent to the plurality of light control units WCL1, WCL2, and WCL3 to prevent the plurality of light control units WCL1, WCL2, and WCL3 from being exposed to moisture or oxygen.

The plurality of capping layers CP1 and CP2 may include an inorganic material. In an embodiment, for example, the plurality of capping layers CP1 and CP2 may be formed by including silicon nitride, aluminum nitride, zirconium nitride, titanium nitride, hafnium nitride, tantalum nitride, silicon oxide, aluminum oxide, titanium oxide, tin oxide, cerium oxide and silicon oxynitride, or a thin metal film and the like with ensured light transmittance. However, the embodiment of the invention is not limited thereto, and the plurality of capping layers CP1 and CP2 may include an organic substance. However, without being limited to what is illustrated, a capping layer may be omitted or further added. However, this is only an example, and in the functional layer FNL according to an alternative embodiment of the invention, one or more of the capping layers CP1 and CP2 may be omitted, and is not limited to any one embodiment.

The sealing layer SL is disposed between the thin film encapsulation layer TFE and a second capping layer CP2 to couple and then seal the display unit DP and the functional layer FNL. In an embodiment, the sealing layer SL may be applied on the front surface of the display panel 100. Accordingly, since bending stress is applied to one component having a combined thickness of the display portion DP, the functional layer FNL, and the sealing layer SL, stress greater than bending stress independently generated in the display unit DP and the functional layer FNL may be applied.

In an embodiment, as described above, the base substrate BS of the display unit DP and the window WD of the functional layer FNL may be components which substantially affect the repulsive force of the display panel 100. In such an embodiment, since the display unit DP and the functional layer FNL is coupled by the sealing layer SL, the repulsive force of the display panel 100 as a single component in which the base substrate BS and the window WD are combined may be generated. Accordingly, the display panel 100 according to an embodiment of the invention has high repulsive force, so that the coupling member 300 (see FIG. 2) having coupling force which opposes the corresponding repulsive force is desired to maintain a curved shape. According to the invention, by including the coupling member 300, the display panel 100 having high repulsive force may be stably attached to the bottom chassis 200 (see FIG. 2).

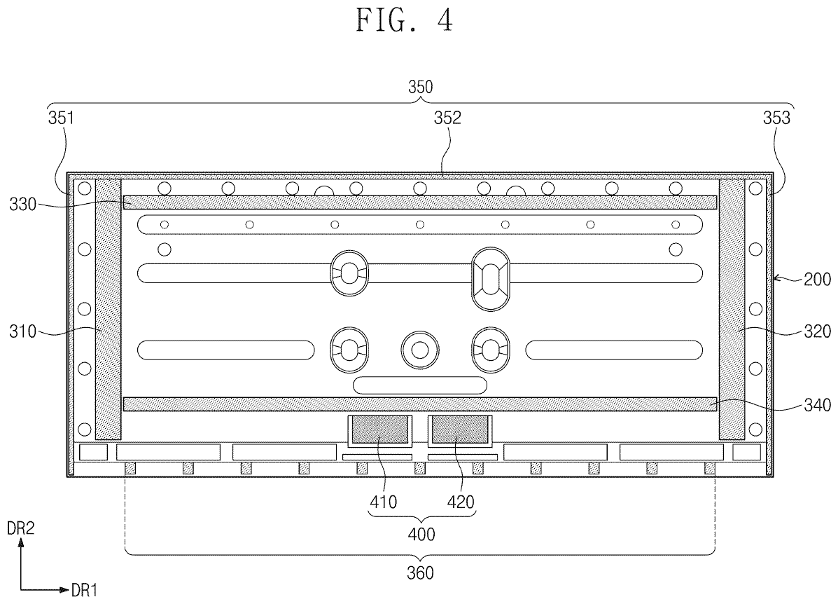

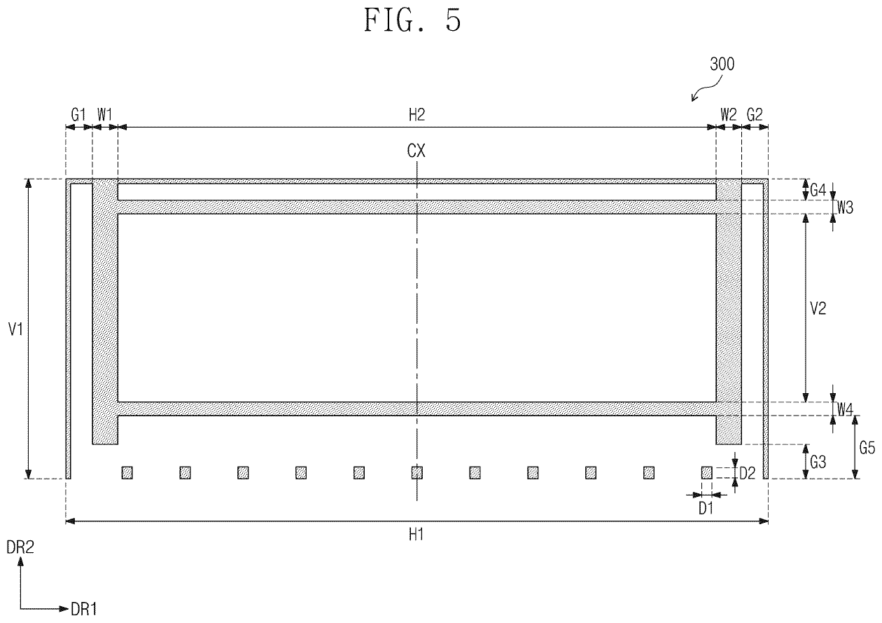

FIG. 4 is a plan view illustrating a part of the configuration of a display apparatus according to an embodiment of the invention. FIG. 5 is a plan view of a coupling member according to an embodiment of the invention. In FIG. 4, the display panel 100 is omitted, and only the bottom chassis 200 and the coupling member 300 are illustrated. Hereinafter, an embodiment of the invention will be described with reference to FIG. 4 and FIG. 5.

In an embodiment, as illustrated in FIG. 4, the coupling member 300 may include a plurality of coupling parts 310, 320, 330, and 340. The coupling parts 310, 320, 330, and 340 may be respectively disposed in corresponding regions in the bottom chassis 200. In an embodiment, the coupling parts 310, 320, 330, and 340 are disposed spaced apart from each other, but some components may be disposed partially overlapping or in contact with each other, and are not limited to any one embodiment.

Coupling parts 310, 320, 330, 340, 350, and 360 may include first to sixth coupling parts 310, 320, 330, 340, 350, and 360. The first coupling part 310 and the second coupling part 320 may be the same (e.g., having a same shape and a same size) as each other and be parallel to each other. In an embodiment, the first coupling part 310 may have a bar shape which has short sides extending along the first direction DR1 and long sides extending along the second direction DR2. In such an embodiment, the second coupling part 320 may have a bar shape which has short sides extending along the first direction DR1 and long sides extending along the second direction DR2.

The first coupling part 310 and the second coupling part 320 are disposed spaced apart from each other in the first direction DR1. When viewed from the display surface IS (see FIG. 1) in third direction DR3, the first coupling part 310 is disposed on a left side portion of the bottom chassis 200, and the second coupling part 320 is disposed on a right side portion thereof.

The first coupling part 310 and the second coupling part 320 may prevent the repulsive force of the display panel 100 (see FIG. 1). Accordingly, the first coupling part 310 and the second coupling part 320 may be disposed spaced apart at an equal distance from a central axis of the display panel 100. The first coupling part 310 may prevent the left portion of the display panel 100 from escaping from the bottom chassis 200 due to repulsive force. The second coupling part 320 may prevent the right portion of the display panel 100 from escaping from the bottom chassis 200 due to repulsive force.

The third coupling part 330 and the fourth coupling part 340 may be the same (e.g., having a same shape and a same size) as each other and be parallel to each other. In an embodiment, the third coupling part 330 may have a bar shape which has long sides extending along the first direction DR1 and short sides extending along the second direction DR2. In such an embodiment, the fourth coupling part 340 may have a bar shape which has long sides extending along the first direction DR1 and short sides extending along the second direction DR2. That is, the third coupling part 330 and the fourth coupling part 340 may have a shape respectively crossing the first coupling part 310 and the second coupling part 320.

The third coupling part 330 and the fourth coupling part 340 are disposed spaced apart from each other in the second direction DR2. When viewed from the display surface IS in the third direction DR3, the third coupling part 330 is disposed on an upper side portion of the bottom chassis 200, and the fourth coupling part 340 is disposed on a lower side portion thereof.

The third coupling part 330 and the fourth coupling part 340 respectively connect the upper side portion and the lower side portion of the display panel 100 to the bottom chassis 200. The third coupling part 330 and the fourth coupling part 340 includes a central axis, and may extend along a direction crossing the central axis to couple various curved sections of the display panel 100 with the bottom chassis 200. The third coupling part 330 may be disposed adjacent to the upper end of the display panel 100, and the fourth coupling part 340 may be disposed on the upper side portion of a region in which a circuit board 400 including a power board 410 and an image board 420 is disposed. The third coupling part 330 and the fourth coupling part 340 may stably couple the display panel 100 and the bottom chassis 200 on each of the upper portion, a lower left portion and a lower right side portion while forming a frame shape together with the first coupling part 310 and the second coupling part 320.

Among the coupling member 300, the fifth coupling part 350 is disposed at an outermost periphery to couple an edge of the bottom chassis 200 to an edge of the display panel 100. The fifth coupling part 350 may include a plurality of portions divided based on an extension direction thereof. In an embodiment, the fifth coupling part 350 may include a first portion 351, a second portion 352, and a third portion 353.

The first portion 351 has a bar shape extending along the second direction DR2. The first portion 351 is disposed at the left end of the edge of the bottom chassis 200. The second portion 352 has a bar shape extending along the first direction DR1. The second portion 352 is bent from the first portion 351 and is extending from an end of the first portion 351. The second portion 352 is disposed at the upper end of the edge of the bottom chassis 200. The third portion 353 has a bar shape extending along the first direction DR1. The third portion 353 is bent from the second portion 352 and is extending from an end of the second portion 352. The third portion 353 may be spaced apart from the first portion 351 and parallel thereto in the first direction DR1. The third portion 353 is disposed at the right end of the edge of the bottom chassis 200.

The fifth coupling part 350 seals the edge of the display panel 100 and the edge of the bottom chassis 200, and thus, may prevent foreign substances from penetrating a space between the display panel 100 and the bottom chassis 200. Accordingly, to the fifth coupling part 350 may effectively prevent moisture or dust from entering between the display panel 100 and the bottom chassis 200.

The sixth coupling part 360 is disposed on the lower side edge portion of the bottom chassis 200. The sixth coupling part 360 may include a plurality of patterns arranged in the first direction DR1. In an embodiment, as shown in FIG. 4, each of the patterns may be in a dot shape (or a small square shape), but the embodiment of the invention is not limited thereto.

The sixth coupling part 360 is disposed in spaces defined on a lower side of the edge portion of the bottom chassis 200 to seal the corresponding spaces. The spaces may be spaces between a plurality of circuit boards (example: flexible circuit board) connected to the display panel 100. The sixth coupling part 360 may be divided into a plurality of patterns to seal each of the spaces. Accordingly, the sixth coupling part 360 may effectively prevent moisture or dust from entering between the display panel 100 and the bottom chassis 200.

Hereinafter, with reference to FIG. 5, the coupling member 300 will be described in greater detail. To facilitate the description, FIG. 5 shows an embodiment where the first to fifth coupling parts 310 to 350 are integrally formed as a single body in which portions corresponding to the first to fifth coupling parts 310 to 350 are connected to each other.

A first horizontal length H1 may correspond to the length in the first direction DR1 occupied by the coupling member 300. The first horizontal length H1 may be substantially defined by the length of a long side of the second portion 352 of the fifth coupling part 350. The first horizontal length H1 may substantially correspond to the width of the bottom chassis 200 in the first direction DR1 or the width of the display panel 100 in the first direction DR1 within a process error range.

A first vertical length V1 may correspond to the length in the second direction DR2 occupied by the coupling member 300. The first vertical length V1 may be substantially defined by the length of a long side of the first portion 351 of the fifth coupling part 350, or the length of a long side of the third portion 353 thereof. The first vertical length V1 may substantially correspond to the width of the bottom chassis 200 in the second direction DR2 or the width of the display panel 100 in the second direction DR2 within a process error range.

A first width W1 and a second width W2 may respectively correspond to the length of a short side of the first coupling part 310 and the length of a short side of the second coupling part 320. Since the first coupling part 310 and the second coupling part 320 provide coupling force which resists the repulsive force of the display panel 100, the increase or decrease of the coupling force may be determined based on the first width W1 and the second width W2 which affect an adhesive area. If the adhesive area is too small, it may be difficult to provide the coupling force which opposes the repulsive force. If the adhesive area is too large, rework properties may be reduced, which may increase process costs. According to an embodiment of the invention, each of the first width W1 and the second width W2 may be a range of approximately 15 millimeters (mm) to approximately 40 mm. Accordingly, a display apparatus capable of ensuring both coupling force and rework properties may be provided.

In an embodiment, as shown in FIG. 5, the first width W1 and the second width W2 may have the same size as each other. However, FIG. 5 merely shows an embodiment where a display panel has a same repulsive force at positions opposing each other with respect to a central axis, and alternatively, the first width W1 and the second width W2 may be different from each other depending on the difference in coupling force to be provided, and the embodiment of the invention is not limited to any one embodiment.

First to third gaps G1, G2, and G3 may be gaps spaced apart from the outer periphery of the bottom chassis 200 of each of the first coupling part 310 and the second coupling part 320. In an embodiment, the first gap G1 may correspond to a distance by which the first coupling part 310 is spaced apart inward from the left end of the bottom chassis 200. The second gap G2 may correspond to a distance by which the second coupling part 320 is spaced apart inward from the right end of the bottom chassis 200.

In general, in a curved display panel, repulsive force increases as the distance from a central axis increases. The first gap G1 and the second gap G2 may substantially mean placement positions of the first coupling part 310 and the second coupling part 320. Accordingly, a section having repulsive force to be mitigated by the first coupling part 310 and the second coupling part 320 may be determined depending on the first gap G1 and the second gap G2. If the first gap G1 and the second gap G2 are too big, a coupling part may be disposed in a region in which repulsive force is not great, so that it may be difficult to reduce process costs to a minimum. According to an embodiment of the invention, each of the first gap G1 and the second gap G2 may be in a range of approximately 4% to approximately 7% of a total length of the bottom chassis 200 in the first direction DR1. For example, each of the first gap G1 and the second gap G2 may be approximately 55 of the total length. That is, each of the first gap G1 and the second gap G2 may be approximately 5% of the first horizontal length H1. In an embodiment, for example, in a 34-inch sized display panel, each of the first gap G1 and the second gap G2 may be approximately 40 mm or less. According to an embodiment of the invention, it is possible to selectively dispose the coupling parts 310 and 320 only in a region in which resistance is desired against repulsive force without increasing the first width W1 and the second width W2, such that process costs may be reduced while achieving improved assembly properties and rework properties.

In an embodiment, the first gap G1 and the second gap G2 may have the same size as each other as shown in FIG. 5. However, FIG. 5 merely shows an embodiment where a display panel has the same repulsive force at positions opposing each other with respect to a central axis, and alternatively, the first gap G1 and the second gap G2 may be different from each other depending on the difference in coupling force to be provided, and the embodiment of the invention is not limited to any one embodiment.

The third gap G3 may correspond to a distance by which the first coupling part 310 and the second coupling part 320 are spaced apart inward from the lower end of the bottom chassis 200. The third gap G3 may become one factor for determining the length of long sides of the first coupling part 310 and the second coupling part 320, and may affect adhesive areas of the first coupling part 310 and the second coupling part 320. As the third gap G3 increases, the coupling force of the first coupling part 310 and the second coupling part 320 may be reduced. The smaller the third gap G3, the greater the coupling force, but rework properties may decrease and process costs may increase. According to the invention, the third gap G3 may be approximately 15% or less of a first vertical length V1. In an embodiment, for example, in the case of a 34-inch sized display apparatus, the third gap G3 may be approximately 40 mm or less.

The fourth gap G4 may correspond to a distance by which the third coupling part 330 is spaced apart inward from the upper end of the bottom chassis 200. The fourth gap G4 may substantially correspond to the placement position of the third coupling part 330. The third coupling part 330 may complement the second portion 352 in the fifth coupling part 350. That is, the third coupling part 330 may complement the coupling force at the upper end of the bottom chassis 200, which is insufficient with the fifth coupling part 350, and may further block the penetration of foreign substances. According to an embodiment of the invention, the fourth gap G4 may be approximately 10% or less of the first vertical length V1. In an embodiment, for example, in the case of a 34-inch sized display apparatus, the third gap G3 may be approximately 30 mm or less.

The fifth gap G5 may correspond to a distance by which the fourth coupling part 340 is spaced apart inward from the lower end of the bottom chassis 200. The fifth gap G5 may substantially correspond to the placement position of the fourth coupling part 340. The fourth coupling part 340 may complement the sixth coupling part 360. That is, the fourth coupling part 340 may complement the coupling force at the lower end of the bottom chassis 200, which is insufficient with the sixth coupling part 360, and may further block the penetration of foreign substances. According to an embodiment of the invention, the fifth gap G5 may be approximately 25% or less of the first vertical length V1. In an embodiment, for example, in the case of a 34-inch sized display apparatus, the fifth gap G5 may be approximately 70 mm or less.

In an embodiment, each of the first coupling part 310 and the second coupling part 320 may be protruding toward the fourth gap G4 past a third coupling part 330, or protruding toward the fifth gap G5 past a fourth coupling part 340, as shown in FIG. 5. However, this is merely an example, and alternatively, upper ends of each of the first coupling part 310 and the second coupling part 320 may be aligned with the third coupling part 330 or be positioned below the third coupling part 330, and in addition, lower ends of each of the first coupling part 310 and the second coupling part 320 may be aligned with the fourth coupling part 340 or be positioned above the fourth coupling part 340, but the embodiment of the invention is not limited to any one embodiment.

A third width W3 may correspond to the length of a short side of the third coupling part 330. The third width W3 affects the adhesive area of the third coupling part 330 together with the length of a long side of the third coupling part 330. The third width W3 may be relatively smaller than the first width W1 or the second width W2. In an embodiment, for example, the third width W3 may be in a range of approximately 10 mm to approximately 15 mm.

A fourth width W4 may correspond to the length of a short side of the fourth coupling part 340. The fourth width W4 affects the adhesive area of the fourth coupling part 340 together with the length of a long side of the fourth coupling part 340. The fourth width W4 may be relatively smaller than the first width W1 or the second width W2. In an embodiment, for example, the fourth width W4 may be in the range of approximately 10 mm to approximately 15 mm.

A first diameter D1 and a second diameter D2 may correspond to the size of each of patterns constituting the sixth coupling part 360. The first diameter D1 corresponds to the width of a pattern in the first direction DR1, and in an embodiment, may correspond to the length of a side extending along the first direction DR1. The second diameter D2 corresponds to the width of a pattern in the second direction DR2, and an the embodiment, may correspond to the length of a side extending along the second direction DR2. In an embodiment, as shown in FIG. 5, the pattern may be in a quadrangular shape, but this is merely an example, and alternatively, the pattern may be formed in various shapes, such as polygons, circles, ovals, and the like, and is not limited to any one embodiment.

The first diameter D1 and the second diameter D2 substantially determine the adhesion area of the sixth coupling part 360. When the first diameter D1 and the second diameter D2 increase, interference with adjacent circuit boards may occur. When the first diameter D1 and the second diameter D2 decrease, coupling force may be reduced. In an embodiment, the first diameter D1 and the second diameter D2 may be the same as each other, and a total of 11 patterns may be provided to be spaced apart from each other with a same interval. However, this is merely an example, and as long as interference with adjacent circuit boards or electronic components is effectively prevented and sealing may be maintained, the first diameter D1 and the second diameter D2 may be designed in various sizes and be provided in various numbers.

The third coupling part 330 and the fourth coupling part 340 described above complement the coupling force of the fifth coupling part 350 and the sixth coupling part 360. Particularly, in an attachment process of coupling the display panel 100 and the bottom chassis 200, the third coupling part 330 and the fourth coupling part 340 first provide coupling force to the display panel 100 and the bottom chassis 200 earlier than the fifth coupling part 350 or the sixth coupling part 360.

Specifically, the third coupling part 330 is disposed on the side of the fifth coupling part 350 and is coupled first from a central axis section during the attachment of coupling the display panel 100 and the bottom chassis 200, and at this time, desired coupling force may be sequentially provided along a direction away from a central axis. The fourth coupling part 340 is disposed on the side of the sixth coupling part 360 to sequentially provide required coupling force along a direction away from a central axis during the attachment of coupling the display panel 100 and the bottom chassis 200.

The third coupling part 330 has the third width W3, which is greater than that of the fifth coupling part 350 in the second direction DR2, and thus, may easily complement the coupling force of the fifth coupling part 350 which has a relatively small width. In addition, by having the fourth width W4, the fourth coupling part 340 may secure an adhesive area larger than that of the sixth coupling part 360, and thus, may easily complement the coupling force of the sixth coupling portion 360 having a relatively small adhesive area.

A second horizontal length H2 may be the length of the first horizontal length H1 except for the first and second gaps G1 and G2 and the first and second widths W1 and W2. The second horizontal length H2 may correspond to the shortest length of a long side of each of the third coupling part 330 and the fourth coupling part 340. That is, the second horizontal length H2 may correspond to the length of a long side of the third coupling part 330 or the length of a long side of the fourth coupling part 340 in a design in which the third coupling part 330 and the fourth coupling part 340 are disposed between the first coupling part 310 and the second coupling part 320.

A second vertical length V2 may be the length of the first vertical length V1 except for the third and fourth gaps G3 and G4 and the third and fourth widths W3 and W4. The second vertical length V2 may correspond to the shortest length of a long side of each of the first coupling part 310 and the second coupling part 320. That is, the second vertical length V2 may correspond to the length of a long side of the first coupling part 310 or the length of a long side of the second coupling part 320 in a design in which the first coupling part 310 and the second coupling part 320 are disposed between the third coupling part 330 and the fourth coupling part 340.

According to an embodiment of the invention, the coupling member 300 includes the first coupling part 310 and the second coupling part 320, so that coupling force with respect to a section having a specific repulsive force may be improved to improve the assembly stability of the display apparatus DS. In addition, according to an embodiment of the invention, by designing a coupling member in a suitable size and shape according to each region of the display panel 100, the bottom chassis 200 and the display panel 100 may be stably coupled with each other only with the coupling member 300. Accordingly, the display apparatus DS with a reduced thickness and a narrow bezel may be provided.

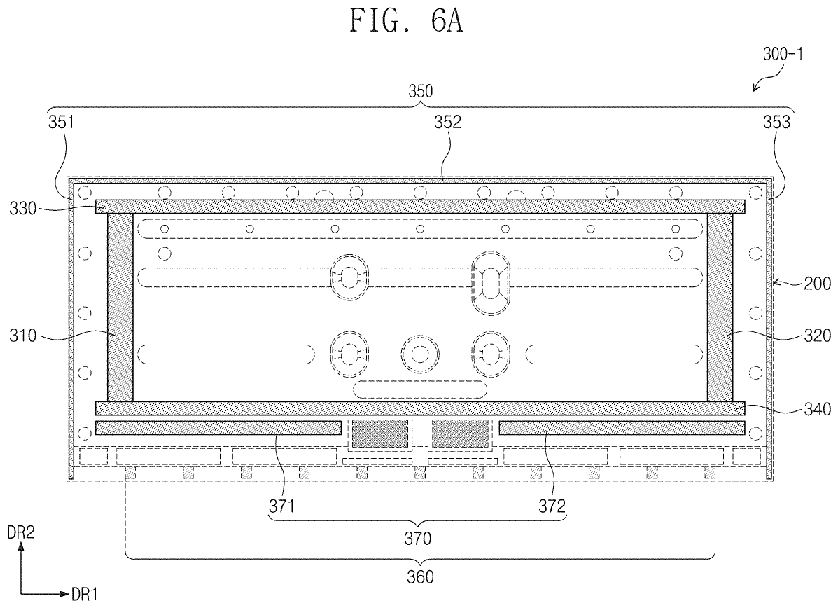

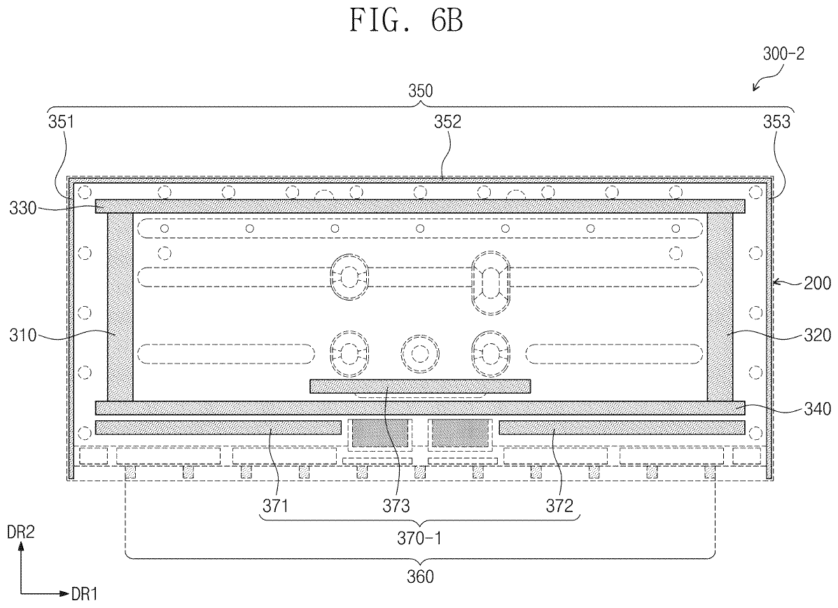

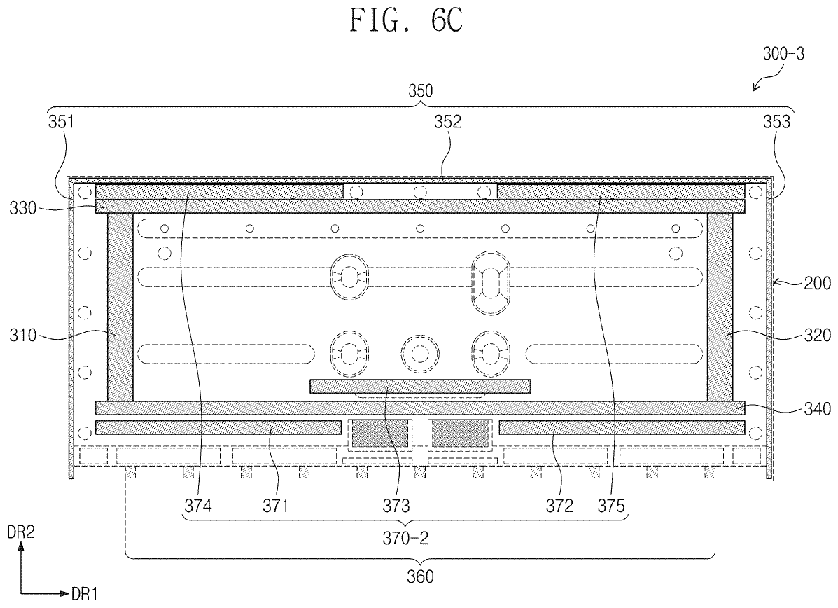

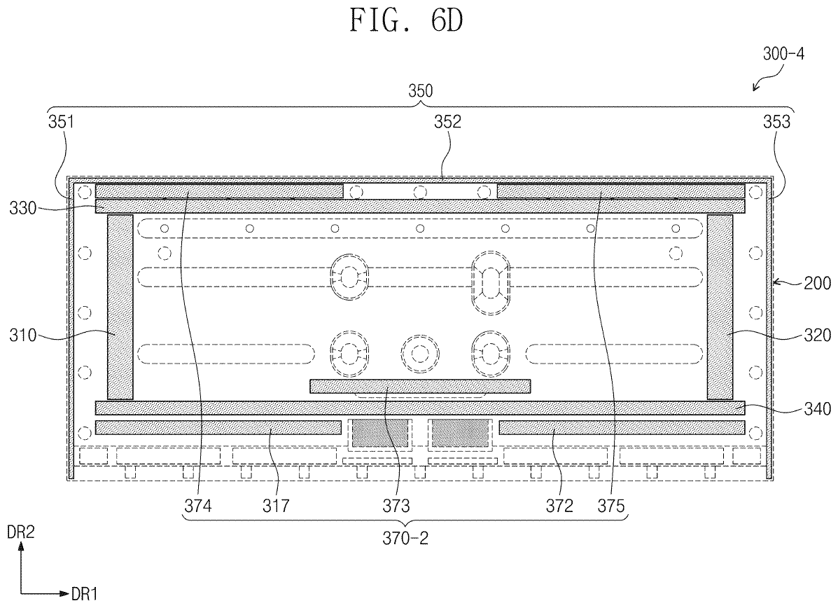

FIG. 6A to FIG. 6D are plan views illustrating coupling members according to embodiments of the invention. To facilitate the description, embodiments of the coupling member 300-1, 300-2, 300-3, and 300-4 are illustrated as being coupled to the bottom chassis 200, and the bottom chassis 200 is illustrated with dotted lines. Hereinafter, with reference to FIG. 6A to FIG. 6D, various embodiments of the coupling member 300-1, 300-2, 300-3, and 300-4 will be described.

Referring to FIG. 6A, in an embodiment, the coupling member 300-1 may further include a seventh coupling part 370. The seventh coupling part 370 may be disposed on a lower side of the fourth coupling part 340. In such an embodiment, the seventh coupling part 370 is disposed between the fourth coupling part 340 and the sixth coupling part 360.

The seventh coupling part 370 may include a first left pattern 371 and a first right pattern 372. The first left pattern 371 is disposed on the left side of the central axis of the display panel 100 (see FIG. 1). The first left pattern 371 may complement the coupling force on the left side of the sixth coupling part 360. The first right pattern 372 is disposed spaced apart from the first left pattern 371 in the first direction DR1. The first right pattern 372 is disposed on the right side of the central axis of the display panel 100. The first right pattern 372 may complement the coupling force on the right side of the sixth coupling part 360.

Referring to FIG. 6B, in an alternative embodiment, the coupling member 300-2 may further include a modified seventh coupling part 370-1. The seventh coupling part 370-1 may further include a center pattern 373 when compared to the seventh coupling part 370 illustrated in FIG. 6A. The center pattern 373 may be disposed on an upper side of the fourth coupling part 340. The center pattern 373 may be disposed at a position overlapping the central axis across the central axis. The center pattern 373 may complement the coupling force in a middle section including the central axis of the sixth coupling part 360.

Referring to FIG. 6C, in an alternative embodiment, the coupling member 300-3 may further include a modified seventh coupling part 370-2. Compared to the seventh coupling part 370-1 illustrated in FIG. 6B, the modified seventh coupling part 370-2 may further include a second left pattern 374 and a second right pattern 375. The second left pattern 374 is disposed on the left side of the central axis of the display panel 100. The second left pattern 374 may complement the coupling force on the left side of the second portion 352 of the fifth coupling part 350. The second right pattern 375 is disposed spaced apart from the second left pattern 374 in the first direction DR1. The second right pattern 375 is disposed on the right side of the central axis of the display panel 100. The second right pattern 375 may complement the coupling force on the right side of second portion 352.

According to an embodiment of the invention, the coupling member 300-1, 300-2 or 300-3 further include the seventh coupling part 370, 370-1 or 370-2, and thus, may easily complement the coupling force of the fifth coupling part 350 and the sixth coupling part 360 in the attachment step of the display panel 100 and the bottom chassis 200. Therefore, a stable assembly process of a display apparatus may be achieved.

Referring to FIG. 6D, in an alternative embodiment of the coupling member 300-4, the sixth coupling part 360 may be omitted. The coupling member 300-4 may include or be composed of first to fifth coupling parts 310, 320, 330, 340, and 350, and the seventh coupling part 370. In such an embodiment, sealing or coupling at a lower end of the display panel 100 may be achieved by the fourth coupling part 340 and the seventh coupling part 370. According to an embodiment of the invention, by omitting the sixth coupling part 360 composed of a relatively large number of patterns to prevent interference between circuit boards or electronic components, the design of the coupling member 300-4 may be simplified and process costs may be reduced.

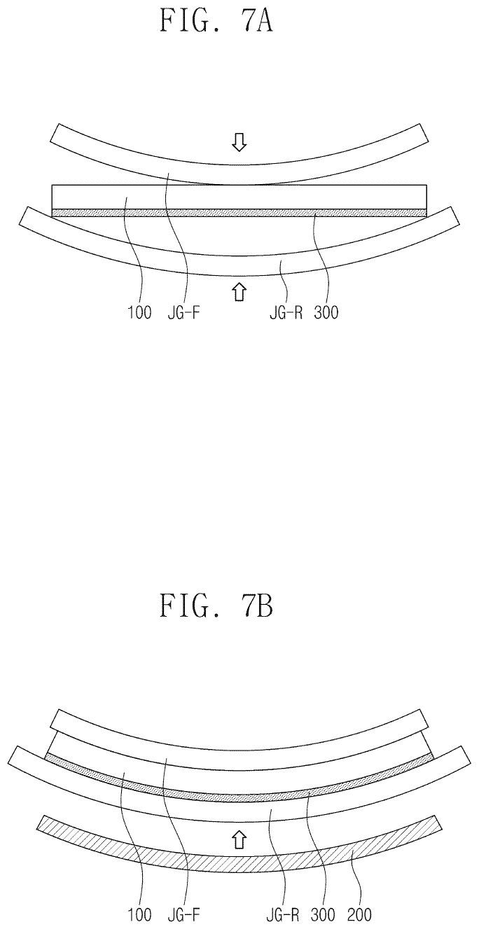

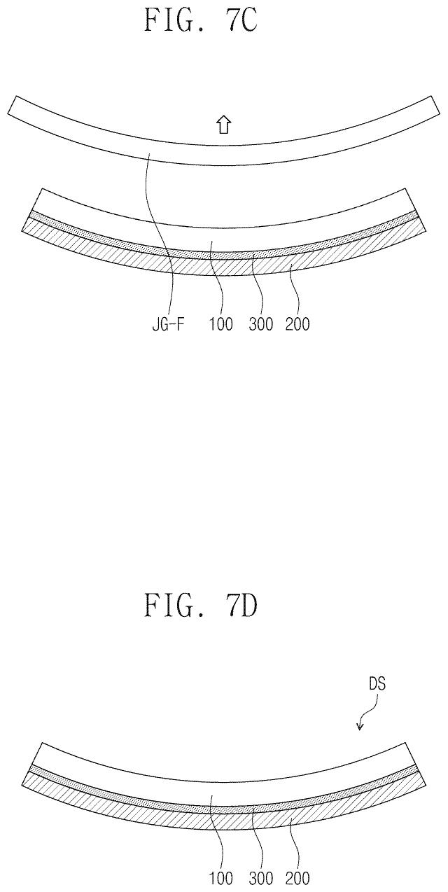

FIG. 7A to FIG. 7D are cross-sectional views schematically illustrating a process of assembling a display apparatus according to an embodiment of the invention. Hereinafter, with reference to FIG. 7A to FIG. 7D, an embodiment of a process of assembling a display apparatus according to the invention will be described. In FIG. 7A to FIG. 7D, the same reference numerals are given to the same components as those described with reference to FIG. 1 to FIG. 6D, and any repetitive detailed descriptions thereof will be omitted.

Referring to FIG. 7A, the coupling member 300 may be attached to the rear surface of the display panel 100 to be provided to jigs JG-F and JG-R. The jigs JG-F and JG-R may include a front jig JG-F provided on a front surface side of the display panel 100 and a rear jig JG-R provided on a rear surface side of the display panel 100.

Thereafter, referring to FIG. 7B, the jigs JG-F and JG-R apply force to the display panel 100 in the direction of the arrow to bend the display panel 100. In such a process, the coupling member 300 may be bent to fit the shape of the display panel 100. In FIG. 7B, it is illustrated that the rear jig JG-R and the coupling member 300 are attached, but this is only illustrated to facilitate the description, and the rear jig JG-R may actually come into contact with a rear surface of the display panel 100 in which the coupling member 300 is not disposed, or a release film may be attached to the rear surface of the coupling member 300 and the release film may come into contact with the rear jig JG-R. Accordingly, direct coupling or attachment between the rear JG-R and the coupling member 300 may not occur.

Thereafter, referring to FIG. 7B and FIG. 7C, as the bottom chassis 200 is attached to the coupling member 300, the rear jig JG-R may be removed. In such a process, the front jig JG-F may be maintained in a state in which force is applied to the front surface of the display panel 100. Accordingly, by maintaining a curved shape of the display panel 100 during a process of attaching the bottom chassis 200 and the coupling member 300, it is possible to minimize the repulsive force of the display panel 100. Therefore, it is possible to prevent the de-lamination of the display panel 100 from the bottom chassis 200 after the assembly, and the assembly stability of the display apparatus DS may be improved.

In such a process, the attachment between the bottom chassis 200 and the coupling member 300 may be sequentially performed starting from a central axis first and moving away from the central axis. Accordingly, the attachment between the third coupling part 330 (see FIG. 4) or the fourth coupling part 340 (see FIG. 4) of the coupling member 300 and the bottom chassis 200 is first performed, so that the third coupling part 330 (see FIG. 4) or the fourth coupling part 340 (see FIG. 4) may serve to provide initial coupling force between the bottom chassis 200 and the display panel 100. Thereafter, a section coupled by the first coupling part 310 (see FIG. 4) and the second coupling part 320 (see FIG. 4), thereby having high repulsive force may be stably attached without an alignment error or the like.

Thereafter, referring to FIG. 7D, as the front jig is removed, the display apparatus DS is formed. As the front jig (JG-F) is removed, the repulsive force of the display panel 100 may be transmitted to the coupling member 300 and the bottom chassis 200. According to an embodiment of the invention, by providing the coupling member 300 configured based on the repulsive force provided to the display panel 100, the assembly of a stable display apparatus capable of resisting the repulsive may be achieved. In such an embodiment, since the attachment is not performed with respect to the front surface of the display panel 100, a rework process may be easily performed, and since a minimum adhesive area may be designed, process costs may also be reduced.

According to embodiments of the invention, the assembly stability of a display apparatus including a curved display panel may be improved. In addition, according to embodiments of the invention, degradation in rework properties may be prevented and process costs may be reduced. In addition, according to embodiments of the invention, a curved display device with a narrow bezel may be provided.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display apparatus comprising:
a display panel including an upper end and a lower end extending in a first direction and a left end and a right end extending along a second direction crossing the first direction, wherein the display panel is curved with respect to a central axis extending along the second direction;
a bottom chassis disposed on a rear surface of the display panel; and
a coupling member disposed between the display panel and the bottom chassis to attach the display panel and the bottom chassis to each other, wherein the coupling member comprising;
a first coupling part extending along the first direction, spaced apart from the central axis and disposed adjacent to the left end of the display panel;
a second coupling part parallel to the first coupling part, spaced apart from the first coupling part having the central axis interposed therebetween and disposed adjacent to the right end of the display panel;
a third coupling part extending along the second direction and crossing the central axis;
a fourth coupling part parallel to the third coupling part and crossing the central axis; and
a fifth coupling part disposed along at least a portion of an edge of the display panel and disposed outside of the first to fourth coupling parts.

2. The display apparatus of claim 1, wherein the bottom chassis covers the rear surface of the display panel and exposes a side surface of the display panel.

3. The display apparatus of claim 1, wherein the fifth coupling part comprises:
a first portion attached to the left end of the display panel;
a second portion attached to the right end of the display panel and bent from the first portion; and
a third portion attached to the upper end of the display panel and bent from the second portion.

4. The display apparatus of claim 3, wherein the coupling member further comprises a sixth coupling part disposed on a lower side of the fourth coupling part, and attached to the lower end of the display panel, wherein the sixth coupling part includes a plurality of patterns arranged in the second direction.

5. The display apparatus of claim 1, wherein a separation distance between the first coupling part and the left end of the display panel is in a range of about 4% to about 7% of a length of the upper end of the display panel.

6. The display apparatus of claim 1, wherein a separation distance between the first coupling part and the lower end of the display panel is about 40 mm or less.

7. The display apparatus of claim 1, the coupling member further comprises a seventh coupling part disposed on a lower side of the fourth coupling part, and disposed between the first coupling part and the second coupling part, wherein the seventh coupling part includes a first left pattern and a first right pattern disposed spaced apart from each other in the first direction.

8. The display apparatus of claim 7, wherein the seventh coupling part further comprises a center pattern disposed between the fourth coupling part and the third coupling part, disposed between the first coupling part and the second coupling part, and overlapping the central axis on a plane.

9. The display apparatus of claim 8, wherein the seventh coupling part further comprises a second left pattern and a second right pattern disposed between the third coupling part and the fifth coupling part, and disposed spaced apart from each other in the first direction.

10. The display apparatus of claim 1, wherein the display panel comprises:
a display unit including:
a base substrate;
a light emitting element disposed on the base substrate; and
an encapsulation layer disposed on the light emitting element;
a functional unit including:
a window substrate facing the base substrate; and
a light control layer material on a rear surface of the window substrate and including a wavelength conversion material; and
a sealing layer disposed between the display unit and the functional unit, wherein the sealing layer is disposed on a front surface of the display panel.

11. The display apparatus of claim 10, wherein the wavelength conversion materials comprise quantum dots.

12. The display apparatus of claim 10, wherein each of the base substrate and the window substrate comprises glass.

13. The display apparatus of claim 1, wherein the coupling member is a foam-type tape.

14. A display apparatus comprising:
a display panel including an upper end and a lower end extending in a first direction and a left end and a right end extending along a second direction crossing the first direction, wherein the display panel is curved with respect to a central axis extending along the second direction;
a bottom chassis disposed on a rear surface of the display panel; and
a coupling member disposed between the display panel and the bottom chassis to attach the display panel and the bottom chassis to each other, wherein the coupling member comprises;
a first coupling part parallel to the central axis and disposed adjacent to the left end;
a second coupling part parallel to the central axis, spaced apart from the first coupling part with the central axis interposed therebetween and disposed adjacent to the right end; and
a third coupling part extending along the left end, the upper end, and the right end,
wherein the first coupling part and the second coupling part are disposed in a space surrounded by the third coupling part.

15. The display apparatus of claim 14, wherein each of a separation distance between the first coupling part and the left end and a separation distance between the second coupling part and the right end is in a range of about 4% to about 7% of a length of the upper end of the display panel.

16. The display apparatus of claim 14, wherein each of a separation distance between the first coupling part and the lower end and a separation distance between the second coupling part and the lower end is about 40 mm or less.

17. The display apparatus of claim 14, wherein the coupling member further comprises a fourth coupling part and a fifth coupling part, each of which is extending along the first direction and disposed spaced apart from each other in the second direction, and each of which is disposed overlapping the central axis, wherein the fourth coupling part and the fifth coupling part are disposed in a space surrounded by the third coupling part.

18. The display apparatus of claim 17, wherein the coupling member further comprises a plurality of first patterns disposed adjacent to the fifth coupling part and spaced apart from each other.

19. The display apparatus of claim 18, wherein the coupling member further comprises a plurality of second patterns disposed adjacent to the fourth coupling part, spaced apart from each other in the first direction, and spaced apart from the first patterns in the second direction, wherein the second patterns are spaced apart from each other with the central axis interposed therebetween.

20. The display apparatus of claim 14, wherein the display panel comprise quantum dots.
